(19) United States
(12) Patent Application Publication
(10) Pub. No.: US 2025/0220913 A1
(43) Pub. Date: Jul. 3, 2025

(54) SEMICONDUCTOR DEVICE

(71) Applicant: Kioxia Corporation, Tokyo (JP)

(72) Inventors: Hiroyuki KUTSUKAKE, Kuwana Mie (JP); Toshifumi HASHIMOTO, Fujisawa Kanagawa (JP); Nobuaki OKADA, Kawasaki Kanagawa (JP)

(73) Assignee: Kioxia Corporation, Tokyo (JP)

(21) Appl. No.: 18/827,723

(22) Filed: Sep. 7, 2024

(30) Foreign Application Priority Data
Dec. 28, 2023 (JP) 2023-223664

(51) Int. Cl. H10B 43/40; G11C 16/04; G11C 16/08; G11C 16/30; H10B 43/27

(52) U.S. Cl. CPC H10B 43/40; G11C 16/0483; G11C 16/08; G11C 16/30; H10B 43/27

(57) ABSTRACT

A semiconductor device comprises a control wiring connected to a gate of a first transistor, a second transistor including a first terminal and a second terminal, and a first gate having the control wiring, wherein the first terminal has a first voltage input thereto, wherein the first voltage is provided to turn on the first transistor, a third transistor including a third terminal and a fourth terminal, and a second gate, wherein the third terminal is connected to the second terminal, the fourth terminal controls a voltage of the control wiring, a fourth transistor including a fifth terminal and a sixth terminal, and a third gate, wherein the fourth transistor is turned on by a second control signal, and a capacitor configured to boost, by capacitive coupling, a second voltage output from the fourth terminal in a state in which the first transistor and the second transistor are turned on.

### CROSS REFERENCE TO RELATED APPLICATIONS

This application is based upon and claims the benefit of priority from the prior Japanese Patent Application No. 2023-223664, filed on Dec. 28, 2023, the entire contents of which are incorporated herein by reference.

### FIELD

Embodiments described herein relate generally to a semiconductor device.

### BACKGROUND

A NAND flash memory has been increasingly highly stacked, and a ratio of a high breakdown voltage transistor used for data writing to a chip size tends to increase. In particular, as high stacking progresses, an area of a core circuit including a word line switch transistor that drives a word line and a control line and a circuit that controls a gate voltage of the word line switch transistor increases, and it becomes difficult to reduce a chip size.

### BRIEF DESCRIPTION OF THE DRAWINGS

FIG. 1 is a block diagram illustrating an example of a configuration of a memory system including a semiconductor memory device according to an embodiment;

FIG. 2 is a circuit diagram illustrating an example of a circuit configuration of a memory cell array provided in the semiconductor memory device according to the embodiment;

FIG. 3 is a cross-sectional view illustrating an example of a cross- sectional structure of the semiconductor memory device according to the embodiment;

FIG. 4 is a circuit diagram illustrating an example of a configuration of a row decoder module, a driver module, and a memory cell array of the semiconductor memory device according to the embodiment;

FIG. 5 is a circuit diagram illustrating an example of a configuration of a block decoder included in the semiconductor memory device according to the embodiment;

FIG. 6 is a circuit diagram of a main part of the block decoder according to a first embodiment;

FIG. 7 is a cross-sectional view in a case where a capacitor includes an MOS capacitor;

FIG. 8 is a diagram illustrating a voltage change of a second voltage and a transfer gate line;

FIG. 9 is a diagram illustrating on-current characteristics of a transfer transistor according to the first embodiment;

FIG. 10 is a plan view and a cross-sectional view illustrating a structure of a diode;

FIG. 11 is a cross-sectional view in a case where the diode includes the MOS transistor;

FIG. 12 is a circuit diagram of a block decoder according to a first modification of the first embodiment;

FIG. 13 is a cross-sectional view of two capacitors included in the block decoder according to the first modification;

FIG. 14 is a circuit diagram of a block decoder according to a second modification of the first embodiment;

FIG. 15 is a cross-sectional view of a capacitor according to the second modification;

FIG. 16 is a circuit diagram of a block decoder according to a second embodiment;

FIG. 17 is a cross-sectional view of a capacitor included in the block decoder according to the second embodiment;

FIG. 18 is a diagram illustrating a change in voltage level of a voltage in FIG. 17;

FIG. 19 is a diagram illustrating on-current characteristics of a transfer transistor according to the second embodiment;

FIG. 20 is a block diagram illustrating a configuration on a transmission path of a voltage supplied to each block decoder;

FIG. 21 is a diagram illustrating a path from an input of a second multiplexer in FIG. 20 to a word line for one control signal line;

FIG. 22 is a diagram illustrating a wiring path from a voltage supply circuit to a row decoder module;

FIG. 23 is a block diagram illustrating a connection relationship between the voltage supply circuit and a local charge pump;

FIG. 24 is a circuit diagram illustrating an example of an internal configuration of the local charge pump;

FIG. 25 is a voltage waveform diagram of a signal input to and output from the local charge pump; and

FIG. 26 is a voltage waveform diagram of a block decoder according to a third embodiment.

### DETAILED DESCRIPTION

In general, according to the embodiment, a semiconductor device comprises a control wiring, a second transistor, a third transistor, a fourth transistor, and a capacitor. The control wiring is connected to a gate of a first transistor. The second transistor includes a first terminal and a second terminal each serving as a source or a drain, and a first gate having the control wiring connected thereto. The first terminal has a first voltage input thereto. The first voltage is provided to turn on the first transistor; The third transistor includes a third terminal and a fourth terminal each serving as a source or a drain, and a second gate. The third terminal is connected to the second terminal. The fourth terminal controls a voltage of the control wiring. The third transistor is turned on by a first control signal input to the second gate when the first transistor is turned on. The fourth transistor includes a fifth terminal and a sixth terminal each serving as a source or a drain, and a third gate. The fourth transistor is turned on by a second control signal input to the third gate when the third transistor is turned on and is turned off by a second control signal input to the third gate when the third transistor is turned off. The capacitor is configured to boost, by capacitive coupling, a second voltage output from the fourth terminal in a state in which the first transistor and the second transistor are turned on to a third voltage higher than the second voltage, and to supply the third voltage to the control wiring.

Hereinafter, embodiments of a semiconductor device will be described with reference to the drawings. Hereinafter, main components of the semiconductor device will be mainly described, but the semiconductor device may have components and functions that are not illustrated or described herein. The following description does not exclude components and functions that are not illustrated or described herein.

### Schematic Configuration of Memory System

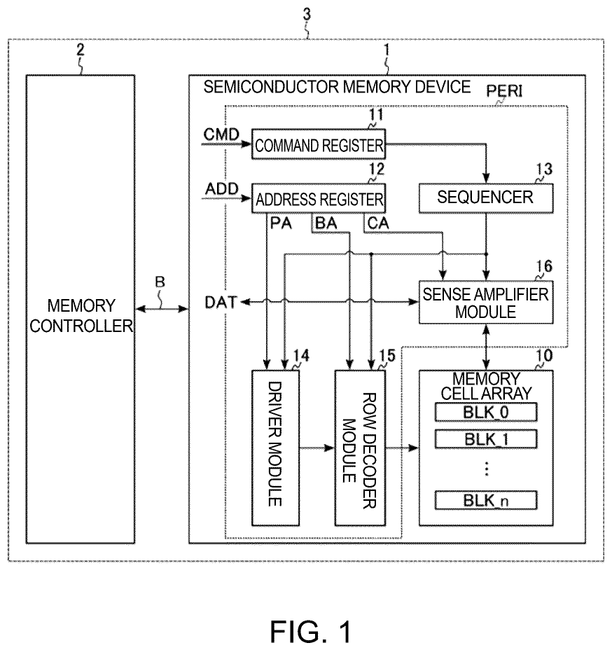

FIG. 1 is a block diagram illustrating a schematic configuration of a memory system including a semiconductor device according to an embodiment. It is noted that, in the present specification, a description will be mainly given as to an example in which the semiconductor device according to the embodiment is applied to a semiconductor memory device.

A memory system 3 includes a semiconductor memory device 1 and a memory controller 2.

The memory system 3 is, for example, a memory card such as an SD™ card, a universal flash storage (UFS), and a solid state drive (SSD). The memory system 3 is configured to be connected to an external host device (not illustrated).

The memory controller 2 includes, for example, an integrated circuit such as a system-on-a-chip (SoC). The memory controller 2 controls the semiconductor memory device 1 based on a request from the host device. Specifically, for example, the memory controller 2 writes data requested to be written by the host device to the semiconductor memory device 1. In addition, the memory controller 2 reads data requested to be read from the host device from the semiconductor memory device 1 and transmits the read data to the host device.

The semiconductor memory device 1 is, for example, a NAND flash memory. The semiconductor memory device 1 stores data in a nonvolatile manner. The semiconductor memory device 1 is connected to the memory controller 2 via a NAND bus B.

The NAND bus B is, for example, a single data rate (SDR) interface, a toggle double data rate (DDR) interface, or an open NAND flash interface (ONFI) compliant bus.

### Internal Configuration of Semiconductor Memory Device

Hereinafter, an internal configuration of the semiconductor memory device 1 according to the embodiment will be described with reference to the block diagram illustrated in FIG. 1. The semiconductor memory device 1 includes, for example, a memory cell array 10 and a peripheral circuit PERI. The peripheral circuit PERI includes a command register 11, an address register 12, a sequencer 13, a driver module 14, a row decoder module 15, and a sense amplifier module 16.

The memory cell array 10 includes a plurality of blocks BLK0 to BLKn (n is an integer of 1 or more). The block BLK is a set of a plurality of memory cell transistors capable of storing data in a nonvolatile manner, and is used, for example, as a data erasing unit. Further, a plurality of bit lines and a plurality of word lines are provided in the memory cell array 10. One memory cell transistor is associated with, for example, one bit line and one word line.

The command register 11 stores a command CMD received by the semiconductor memory device 1 from the memory controller 2. The command CMD includes, for example, a command for causing the sequencer 13 to execute a read operation, a write operation, an erase operation, and the like.

The address register 12 stores address information ADD received by the semiconductor memory device 1 from the memory controller 2. The address information ADD includes, for example, a page address PA, a block address BA, and a column address CA. For example, the page address PA, the block address BA, and the column address CA are used to select a word line, a block BLK, and a bit line, respectively.

The sequencer 13 controls the entire operation of the semiconductor memory device 1. For example, the sequencer 13 controls the driver module 14, the row decoder module 15, the sense amplifier module 16, and the like based on the command CMD stored in the command register 11, thereby executing the read operation, the write operation, the erase operation, and the like.

The driver module 14 generates a voltage to be used in the read operation, the write operation, the erase operation, and the like. Then, the driver module 14 applies the generated voltage to a signal line corresponding to the selected word line based on, for example, the page address PA stored in the address register 12.

The row decoder module 15 selects one block BLK in the corresponding memory cell array 10 based on the block address BA stored in the address register 12. Then, the row decoder module 15 transfers, for example, the voltage applied to the signal line corresponding to the selected word line to the selected word line in the selected block BLK.

The sense amplifier module 16 transfers data DAT between the memory controller 2 and the memory cell array 10. The data DAT includes write data and read data. More specifically, the sense amplifier module 16 transfers the write data received from the memory controller 2 to the memory cell array 10 in the write operation. In addition, the sense amplifier module 16 executes determination of data stored in the memory cell transistor based on the voltage of the bit line in the read operation. Then, the sense amplifier module 16 transfers the determination result to the memory controller 2 as read data.

### Circuit Configuration of Memory Cell Array

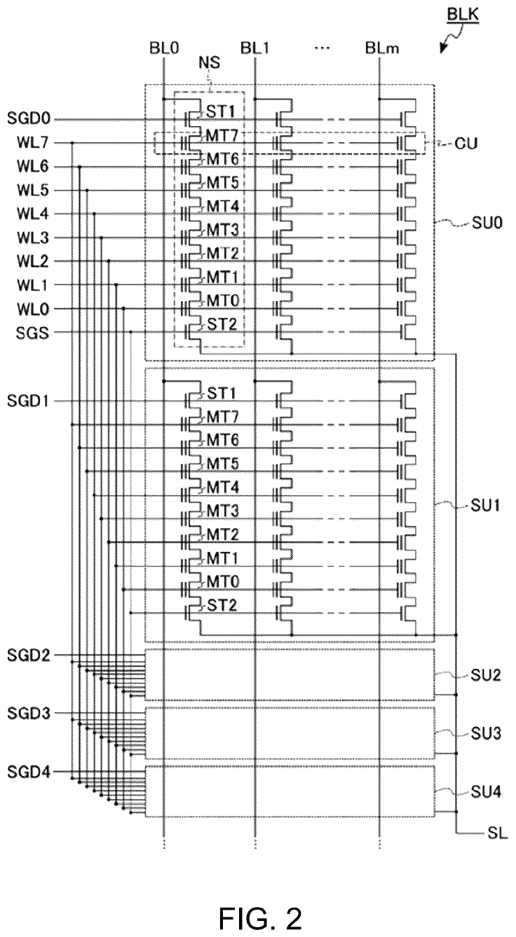

FIG. 2 is a circuit diagram illustrating an example of a circuit configuration of the memory cell array 10 included in the semiconductor memory device according to the embodiment. FIG. 2 illustrates one block BLK among the plurality of blocks BLK included in the memory cell array 10. In the example shown in FIG. 2, the block BLK includes, for example, five string units SU0 to SU4.

Each string unit SU includes a plurality of NAND strings NS associated with bit lines BL0 to BLm (m is an integer of 1 or more). Each NAND string NS includes, for example, memory cell transistors MT0 to MT7 and select transistors ST1 and ST2. Each of the memory cell transistors MT0 to MT7 includes a control gate and a charge storage layer, and stores data in a nonvolatile manner. Each of the select transistors ST1 and ST2 is used to select the string unit SU during various operations. In the following description, the memory cell transistors MT0 to MT7 are also referred to as memory cell transistors MT, respectively.

In each NAND string NS, the memory cell transistors MT0 to MT7 are connected in series. One end of the select transistor ST1 is connected to the associated bit line BL, and the other end of the select transistor ST1 is connected to each of one ends of the memory cell transistors MT0 to MT7 connected in series. One end of the select transistor ST2 is connected to the other ends of the memory cell transistors MT0 to MT7 connected in series. The other end of the select transistor ST2 is connected to a source line SL.

In the same block BLK, the control gates of the memory cell transistors MT0 to MT7 are connected to word lines WL0 to WL7, respectively. Gates of the select transistors ST1 in the string units SU0 to SU4 are connected to select gate lines SGD0 to SGD4, respectively. On the other hand, gates of the plurality of select transistors ST2 are commonly connected to a select gate line SGS. However, the present invention is not limited thereto, and the gates of the plurality of select transistors ST2 may be connected to a plurality of select gate lines different for each string unit SU. In the following description, when the word lines WL0 to WL7 are not distinguished from each other, they are simply referred to as word lines WL. Further, when the select gate lines SGD0 to SGD4 are not distinguished from each other, the select gate lines SGD0 to SGD4 are simply referred to as select gate lines SGD.

Each of the bit lines BL0 to BLm is commonly connected to one NAND string NS included in each string unit SU in the plurality of blocks BLK. Each of the word lines WL0 to WL7 is provided for each block BLK. The source line SL is shared among, for example, the plurality of blocks BLK.

A set of the plurality of memory cell transistors MT connected to the common word line WL in one string unit SU is referred to as, for example, a cell unit CU. For example, a storage capacity of the cell unit CU including the memory cell transistor MT each storing 1-bit data is defined as “1-page data”. The cell unit CU may have a storage capacity of 2-page data or more according to the number of bits of data stored in the memory cell transistor MT.

It is noted that a circuit configuration of the memory cell array 10 included in the semiconductor memory device 1 according to the embodiment is not limited to the configuration described above. For example, the number of string units SU included in each block BLK can be designed to any number. The number of memory cell transistors MT and the number of select transistors ST1 and ST2 included in each NAND string NS can be designed to any number.

### Cross-Sectional Structure of Semiconductor Memory Device

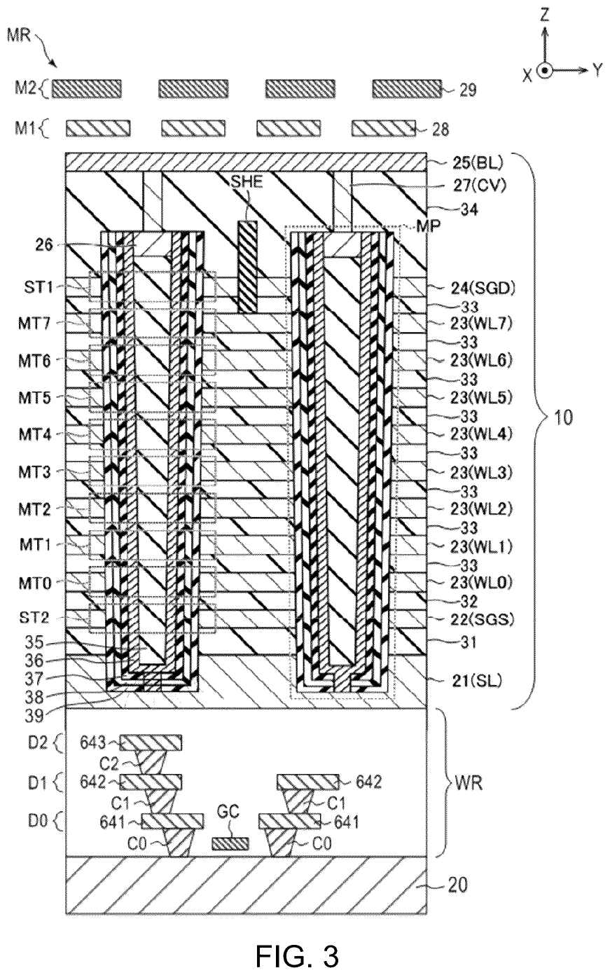

Next, a cross-sectional structure of the semiconductor memory device 1 according to the embodiment will be described with reference to FIG. 3. FIG. 3 is a cross-sectional view illustrating an example of a cross-sectional structure of the semiconductor memory device according to the embodiment. FIG. 3 illustrates a cross-sectional structure including two string units SU among five string units SU included in one block BLK.

It is noted that, in the drawings referred to below, an X direction corresponds to an extending direction of the word line WL, a Y direction corresponds to an extending direction of the bit line BL, and a Z direction corresponds to a vertical direction relative to the surface of a semiconductor substrate on which the semiconductor memory device 1 is formed.

The memory cell array 10 includes conductor layers 21, 22, 24, and 25 provided above a semiconductor substrate 20, a plurality of conductor layers 23, and a plurality of memory pillars MP (only two are illustrated in FIG. 3). In the following description, a direction in which the memory cell array 10 is provided relative to the semiconductor substrate 20 is defined as an upward direction. The opposite direction is defined as a downward direction.

A wiring layer region WR is disposed on the semiconductor substrate 20. The wiring layer region WR has a plurality of wiring layers D0, D1, and D2 vertically stacked with contacts C0, C1, and C2 interposed therebetween. The peripheries of the plurality of wiring layers D0, D1, and D2 are covered with an insulator layer. FIG. 3 illustrates an example in which the wiring layer region has three wiring layers D0, D1, and D2, but the number of wiring layers is freely selected. At least a part of a peripheral circuit such as a row decoder is arranged in the wiring layers D0, D1, and D2.

The conductor layer 21 is stacked on the wiring layer region WR. The conductor layer 21 is formed to have, for example, a plate shape extending along the XY plane. The conductor layer 21 is used as a source line SL. The conductor layer 21 is made of a conductive material, and is made of, for example, an N-type semiconductor doped with impurities, or a metal material such as a laminated film of titanium nitride (TIN), tantalum nitride (TaN), aluminum (Al), tantalum nitride (TaN), and tantalum (Ta), a laminated film of titanium (Ti), titanium nitride (TiN), and tungsten (W), or a laminated film of titanium nitride (TiN) and tungsten silicide (WSi). In addition, the conductor layer 21 may have a laminated structure of a semiconductor and a metal material, such as a laminated film of titanium nitride (TiN), tungsten silicide (WSi), and poly-Si.

An insulator layer 31 is provided on the conductor layer 21. The conductor layer 22 is stacked on the insulator layer 31. The conductor layer 22 is formed to have, for example, a plate shape extending along the XY plane. The conductor layer 22 is used as a select gate line SGS. The conductor layer 22 contains, for example, tungsten (W).

An insulator layer 32 is provided on the conductor layer 22. On the insulator layer 32, eight conductor layers 23 and eight insulator layers 33 are alternately stacked one by one. The conductor layer 23 is formed to have, for example, a plate shape extending along the XY plane. The eight stacked conductor layers 23 are used as the word lines WL0 to WL7 in order from the conductor layer 21 side. The conductor layer 23 contains, for example, tungsten (W).

On the uppermost insulator layer 33, the conductor layer 24 and the insulator layer 34 are stacked in this order. The conductor layer 24 is formed to have, for example, a plate shape extending along the XY plane. The stacked conductor layer 24 is used as a select gate line SGD. The conductor layer 24 contains, for example, tungsten (W). The conductor layer 24 is electrically separated for each string unit SU by, for example, a slit SHE.

The insulator layer 34 is provided on the conductor layer 24. The conductor layer 25 is provided on the insulator layer 34. The conductor layer 25 is formed in a line shape extending in the Y direction, for example, and functions as the bit line BL. The conductor layer 25 contains, for example, copper (Cu).

The plurality of memory pillars MP are provided to extend in the Z direction below the conductor layer 25, and penetrate the conductor layers 22 and 24 and the plurality of conductor layers 23. In addition, a bottom portion of each of the memory pillars MP is located below the insulator layer 31 and is in contact with the conductor layer 21.

Each of the memory pillars MP includes, for example, a core member 35, a semiconductor film 36, a tunnel insulating film 37, a charge storage film 38, a block insulating film 39, and a semiconductor portion 26.

The core member 35 is provided to extend, for example, in the Z direction. The upper end of the core member 35 is included in a layer above the conductor layer 24, and the lower end of the core member 35 is included in a layer below the conductor layer 22. The core member 35 includes, for example, silicon oxide (SiO₂).

The semiconductor film 36 is provided so as to cover the side surface and the lower surface of the core member 35. The upper end of the semiconductor film 36 reaches a position equivalent to the position of the upper end of the core member 35. The lower end of the semiconductor film 36 is in contact with the conductor layer 21. The semiconductor film 36 contains, for example, polysilicon.

The tunnel insulating film 37 covers the side surface of the semiconductor film 36. The tunnel insulating film 37 contains, for example, silicon oxide (SiO₂).

The charge storage film 38 covers the side surface of the tunnel insulating film 37. The charge storage film 38 includes, for example, an insulator capable of storing charges. The insulator is, for example, silicon nitride (SiN).

The block insulating film 39 covers the side surface of the charge storage film 38. The block insulating film 39 contains, for example, silicon oxide (SiO₂).

The semiconductor portion 26 is provided so as to be in contact with the semiconductor film 36 and cover the upper end of the core member 35. A conductor layer 27 functioning as a columnar contact CV is provided at the upper end of the semiconductor portion 26. The upper end of the conductor layer 27 is in contact with the conductor layer 25. The conductor layer 25 has a linear bit line BL extending in the Y direction. In the conductor layer 25, for example, a plurality of bit lines BL are arranged at predetermined intervals in the front-and-back direction of FIG. 3. Each bit line BL and the corresponding memory pillar MP are electrically conducted to each other with the corresponding conductor layer 27 interposed therebetween.

The conductor layer 28 is disposed on the conductor layer 25 with an insulator layer interposed therebetween. The conductor layer 29 is disposed on the conductor layer 28 with an insulator layer interposed therebetween. For example, at least a part of a peripheral circuit of the memory cell array 10 and the like are arranged in the conductor layers 28 and 29. FIG. 3 shows an example in which two conductor layers 28 and 29 are stacked above a conductor layer in which bit lines are arranged, but the number of wiring layers is freely selected. In the present specification, the conductor layer 25 including the bit line may be referred to as a wiring layer M0, the conductor layer 28 disposed thereon may be referred to as a wiring layer M1, and the conductor layer 29 disposed thereon may be referred to as a wiring layer M2.

In the structure of the memory pillar MP described above, a portion at which the memory pillar MP intersects the conductor layer 22 functions as the select transistor ST2. Further, a portion at which the memory pillar MP intersects the conductor layer 23 functions as the memory cell transistor MT. In addition, a portion at which the memory pillar MP intersects the conductor layer 24 functions as the select transistor ST1. In addition, the semiconductor film 36 functions as a channel of each of the memory cell transistors MT0 to MT7 and the select transistors ST1 and ST2. In addition, the charge storage film 38 functions as a charge storage layer of the memory cell transistor MT.

### Overall Configuration of Row Decoder Module

Next, a configuration example of the row decoder module 15 included in the peripheral circuit PERI will be described.

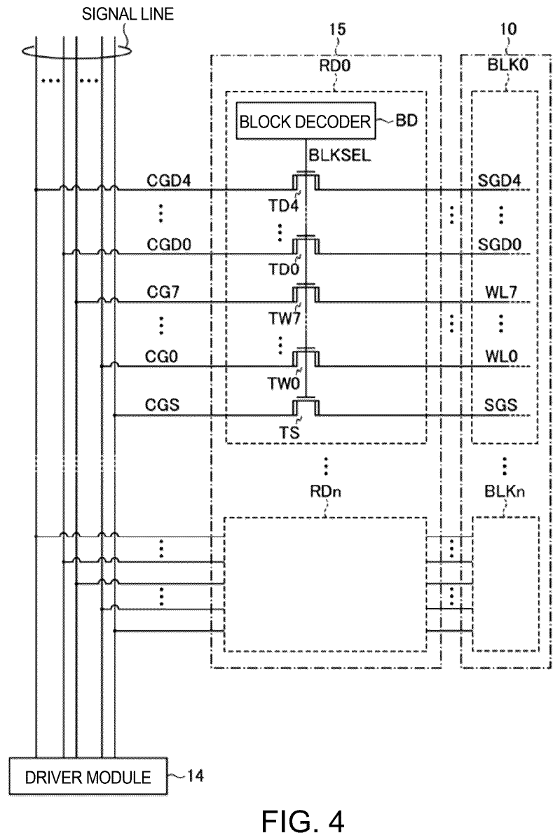

The overall configuration of the row decoder module 15 will be described with reference to FIG. 4. FIG. 4 is a circuit diagram showing an example of configurations of the row decoder module, the driver module, and the memory cell array 10 of the semiconductor memory device according to the embodiment.

The row decoder module 15 includes row decoders RD0 to RDn. The row decoders RD0 to RDn are used to select the block BLK. The row decoders RD0 to RDn are associated with the blocks BLK0 to BLKn, respectively.

Each row decoder RD includes, for example, a block decoder BD, and transfer transistors TW0 to TW7, TS, and TD0 to TD4. Each of the transfer transistors TW0 to TW7, TS, and TD0 to TD4 is, for example, a high breakdown voltage N-channel metal-oxide-semiconductor field effect transistor (MOSFET). The transfer transistors TW0 to TW7 are associated with the word lines WL0 to WL7, respectively. In the following description, when the transfer transistors TW0 to TW7 are not distinguished from each other, they are simply referred to as transfer transistors TW. The transfer transistors TS and TD0 to TD4 are associated with the select gate lines SGS and SGD0 to SGD4, respectively. It is noted that, in the following description, when the transfer transistors TD0 to TD4 are not distinguished from each other, they are simply referred to as transfer transistors TD. In addition, the MOSFET having a high breakdown voltage is a MOSFET in which a physical film thickness of a gate insulating film is 10 nm or more. A gate-source voltage of the high breakdown voltage N-channel MOSFET can be, for example, a voltage of 10 V or more.

The block decoder BD decodes the block address BA. The block decoder BD applies a voltage of a “H (high)” level and a voltage of a “L (low)” level to a transfer gate line BLKSEL, for example, based on a result of the decoding. In the present specification, the transfer gate line BLKSEL may be simply referred to as a control wiring.

The transfer transistors TW0 to TW7, TS, and TD0 to TD4 connect the driver module 14 to the corresponding block BLK with signal lines CG0 to CG7, CGS, and CGD0 to CGD4 interposed therebetween, respectively. In the following description, when the signal lines CG0 to CG7, CGS, and CGD0 to CGD4 are not distinguished from each other, they are simply referred to as signal lines CG.

More specifically, in each row decoder RD, the gate of each transfer transistor TD is connected to the transfer gate line BLKSEL. A first end of each transfer transistor TD is connected to the driver module 14 with a corresponding signal line CG among the signal lines CGD0 to CGD4 interposed therebetween. A second end of each transfer transistor TD is connected to a corresponding select gate line SGD among the select gate lines SGD0 to SGD4.

The gate of each of the transfer transistors TW is connected to the transfer gate line BLKSEL. A first end of each transfer transistor TW is connected to the driver module 14 with a corresponding signal line CG among the signal lines CG0 to CG7 interposed therebetween. A second end of each transfer transistor TW is connected to a corresponding word line WL among the word lines WL0 to WL7.

A gate of the transfer transistor TS is connected to the transfer gate line BLKSEL. A first end of the transfer transistor TS is connected to the driver module 14 with the signal line CGS interposed therebetween. A second end of the transfer transistor TS is connected to the select gate line SGS.

When the voltage of the “H” level is applied to the transfer gate line BLKSEL, the transfer transistors TW, TS, and TD go into an ON state. As a result, the voltages of the signal lines CG0 to CG7, CGS, and CGD0 to CGD4 are respectively transferred to the word lines WL0 to WL7, the select gate line SGS, and the select gate lines SGD0 to SGD4 with the transfer transistors TW0 to TW7, TS, and TD0 to TD4 interposed therebetween. When the voltage of the “L” level is applied to the transfer gate line BLKSEL, the transfer transistors TW, TS, and TD go into an OFF state.

### Basic Configuration of Block Decoder BD

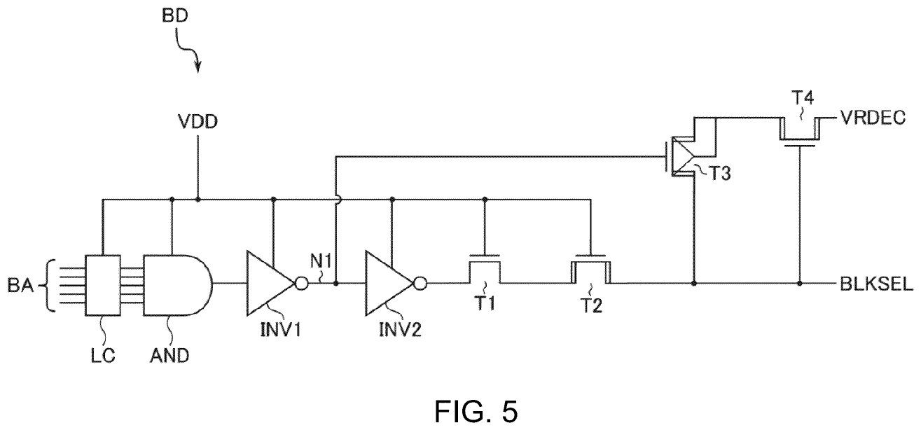

The configuration of the plurality of block decoders BD included in each row decoder RD will be described with reference to FIG. 5. FIG. 5 is a circuit diagram illustrating a basic configuration of the block decoder BD included in the semiconductor memory device according to the embodiment.

As illustrated in FIG. 5, the block decoder BD includes a logic circuit LC, an AND circuit AND, inverters INV1 and INV2, and transistors T1, T2, T3, and T4. The transistors T1, T2, and T4 are, for example, N-channel MOSFETs. The transistor T3 is, for example, a P-channel MOSFET. The transistors T2, T3, and T4 are high breakdown voltage MOSFETs, the gate insulating films of which are thicker in physical film thickness than that of the transistor T1. The physical film thickness of the gate insulating film of each of the transistors T2, T3, and T4 is, for example, 10 nm or more. Furthermore, the gate-source voltage of each of the transistors T2, T3, and T4 can be, for example, a voltage of 10 V or more. On the other hand, the physical film thickness of the gate insulating film of the transistor T1 is, for example, smaller than 10 nm. For example, the gate- source voltage of the transistor T1 is lower than 10 V. In the present specification, the transistor T4 may be referred to as a second transistor, the transistor T3 may be referred to as a third transistor, and the transistor T2 may be referred to as a fourth transistor. In addition, the transistors TD0 to TD4, TW0 to TW7, and TS in FIG. 4 may be collectively referred to as a first transistor.

The block address BA is input from the address register 12 to the first input unit of the logic circuit LC. For example, a power supply voltage VDD is applied to the second input unit of the logic circuit LC. The logic circuit LC is driven by the power supply voltage VDD. A signal based on the block address BA is output from the output unit of the logic circuit LC. When the block address BA input to the logic circuit LC is the block address BA allocated to the block BLK corresponding to the logic circuit LC, the signal of the “H” level is output from the output unit of the logic circuit LC. When the block address BA input to the logic circuit LC is not the block address BA allocated to the block BLK corresponding to the logic circuit LC, the signal of the “L” level is output from the output unit of the logic circuit LC.

A first output unit of the logic circuit LC is connected to the first input unit of the AND circuit AND. For example, the power supply voltage VDD is applied to the second input unit of the AND circuit AND. The AND circuit AND is driven by the power supply voltage VDD. A signal based on an AND operation of the signal output from the output unit of the logic circuit LC is output from the output unit of the AND circuit AND.

The first input unit of the inverter INV1 is connected to the output unit of the AND circuit AND. For example, the power supply voltage VDD is applied to the second input unit of the inverter INV1. The inverter INV1 is driven by the power supply voltage VDD. The output unit of the inverter INV1 is connected to the node N1. An inverted signal of the signal output from the output unit of the AND circuit AND is output from the output unit of the inverter INV1.

The first input unit of the inverter INV2 is connected to the node N1. For example, the power supply voltage VDD is applied to the second input unit of the inverter INV2. The inverter INV2 is driven by the power supply voltage VDD. An inverted signal of the signal output from the output unit of the inverter INV1 is output from the output unit of the inverter INV2.

The first end (for example, the drain) of the transistor T1 is connected to the output unit of the inverter INV2. The power supply voltage VDD is applied to the gate of the transistor T1. The second end (for example, the source) of the transistor T1 is connected to the first end (for example, the drain) of the transistor T2.

The first end of the transistor T2 is connected to the second end (for example, the source) of the transistor T1. The power supply voltage VDD is applied to the gate of the transistor T2. The second end of the transistor T2 is connected to the transfer gate line BLKSEL.

The first end (for example, the drain) of the transistor T3 is connected to the transfer gate line BLKSEL. The gate of the transistor T3 is connected to the node N1. The second end (for example, the source) of the transistor T3 is connected to the transistor T4 together with the back gate of the transistor T3.

The first end (for example, the source) of the transistor T4 is connected to the second end of the transistor T3 and the back gate of the transistor T3. The gate of the transistor T4 is connected to the transfer gate line BLKSEL. A voltage VRDEC is applied to the second end (for example, the drain) of the transistor T4. A high voltage is applied to the second end of the transistor T4 so that the transfer transistors TW, TS, and TD can respectively transfer the voltage supplied to the corresponding signal line CG to the word line WL, the select gate line SGS, and the select gate line SGD by being transferred to the transfer gate line BLKSEL via the transistors T3 and T4.

The transistor T4 switches whether or not to boost the voltage of the gate connected to the transfer gate line BLKSEL depending on the voltage VRDEC used to boost the transfer gate line BLKSEL. The transistor T3 is turned on when the transfer gate line BLKSEL is boosted, and is turned off otherwise. The transistor T2 sets the selected transfer gate line BLKSEL to the high level. The transistor T2 is turned on or off in conjunction with the transistor T3.

With the above configuration, when the corresponding block BLK is selected, the block decoder BD outputs the signal of the “H” level to the transfer gate line BLKSEL. When the corresponding block BLK is not selected, the block decoder BD outputs the signal of the “L” level to the transfer gate line BLKSEL.

As illustrated in FIGS. 1 and 4, each row decoder RD in the row decoder module 15 includes a plurality of block decoders BD, and each block decoder BD is associated with any block. As illustrated in FIG. 5, each block decoder BD performs switching control ON or OFF of the corresponding transfer transistors TW0 to TW7, TS, and TD0 to TD4 on the corresponding transfer gate line BLKSEL. In the present specification, the transfer transistors TW0 to TW7, TS, and TD0 to TD4 may be collectively referred to as a switch circuit group or a word line switch (the fourth transistor) WLSW. Each row decoder RD includes a plurality of switch circuit groups (word line switches) WLSW corresponding to the plurality of block decoders BD.

### First Embodiment

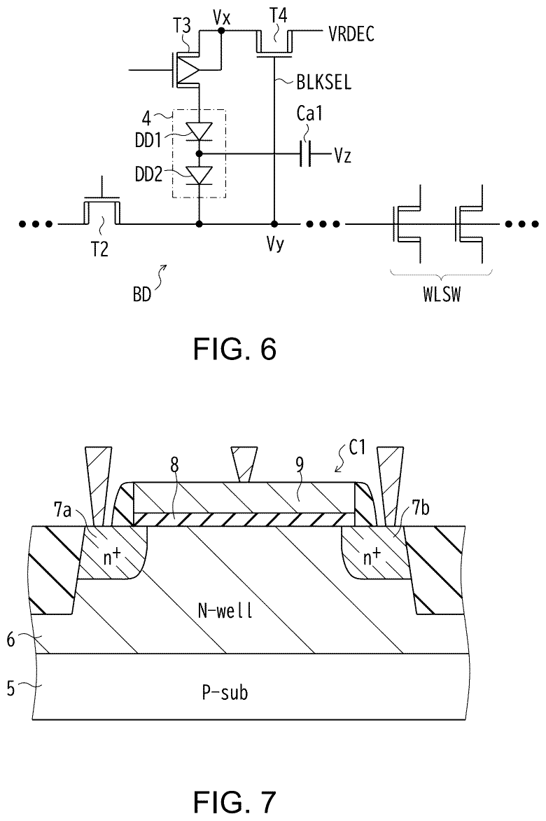

A semiconductor device according to a first embodiment includes a block decoder BD having a configuration different from that of the block decoder BD in FIG. 5. FIG. 6 is a circuit diagram of a main part of the block decoder BD according to the first embodiment. In FIG. 6, the same components as those in FIG. 5 are denoted by the same reference numerals, and differences therebetween will be mainly described below. The block decoder BD according to the first embodiment includes the logic circuit LC, the AND circuit AND, the inverters INV1 and INV2, and the transistor T1, which are similar to those in FIG. 5, but are omitted in FIG. 6.

As illustrated in FIG. 6, the block decoder BD according to the first embodiment controls the voltage of the transfer gate line BLKSEL using the first voltage VRDEC generated by the driver module 14 or the like. The block decoder BD according to the first embodiment includes a capacitor Ca1 and a rectifier circuit 4 in addition to the transistors T1 to T4.

The capacitor Ca1 boosts the transfer gate line BLKSEL by capacitive coupling. As described later, various forms such as an MOS capacitor or an interwiring capacitance can be applied to the capacitor Ca1. Furthermore, the interwiring capacitance can be configured with, for example, metal insulator metal (MIM), metal oxide metal (MOM), or the like.

The rectifier circuit 4 prevents a current due to the boosted voltage of the transfer gate line BLKSEL from flowing back between the drain and the source of the transistor T3. The rectifier circuit 4 includes one or more diodes. It is noted that the diode may be configured by short-circuiting the drain and the gate of the MOS transistor. In the first embodiment, an example in which the rectifier circuit 4 includes two diodes (a first diode and a second diode) DD1 and DD2 connected in series will be described. The anode of the diode DD1 is connected to the drain of the transistor T3. The cathode of the diode DD1 is connected to the anode of the diode DD2. The cathode of the diode DD2 is connected to the transfer gate line BLKSEL.

The transfer gate line BLKSEL is set to a voltage level corresponding to the voltage of one end of the capacitor Ca1. A second voltage Vz, whose voltage level is variable, is applied to one end of the capacitor Ca1. The second voltage Vz is generated at the driver module 14 or elsewhere. The other end of the capacitor Ca1 is connected to an intermediate node Va that connects the cathode of the diode DD1 to the anode of the diode DD2.

FIG. 7 is a cross-sectional view in a case where the capacitor Ca1 includes an MOS capacitor. Two diffusion regions 7a and 7b connected to one end of the capacitor Ca1 are disposed in an N-type well region 6 disposed on a P-type silicon substrate 5. The gate electrode layer 9 connected to the other end of the capacitor Ca1 is disposed above between the two diffusion regions 7a and 7b with a gate insulating film 8 interposed therebetween. The gate electrode layer 9 may be made of a metal material or polysilicon. The thickness of the gate insulating film 8 is any thickness. The transistors T2 to T4 in the block decoder BD are high breakdown voltage transistors, and the gate insulating film 8 is made thicker than the low breakdown voltage transistor T1. The gate insulating film 8 of the MOS capacitor Ca1 illustrated in FIG. 7 may be the same as the high breakdown voltage transistors T2 to T4, or may be the same as the low breakdown voltage transistor T1. The capacitance of the capacitor Ca1 can be adjusted by adjusting at least one of the film thickness and the material of the gate insulating film 8. As described above, for example, the gate insulating film 8 of the MOS capacitor Ca1 has a film thickness equal to or less than the film thicknesses of the transistors T1 to T3.

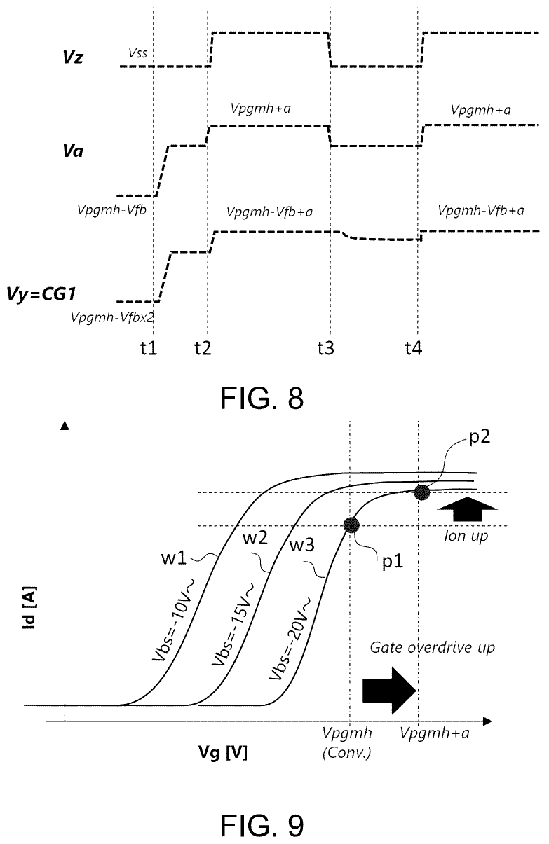

FIG. 8 is a diagram illustrating voltage changes of the second voltage Vz and the transfer gate line BLKSEL. FIG. 8 illustrates voltage waveforms of the second voltage Vz, a voltage of the intermediate node Va between the diodes DD1 and DD2, and a voltage Vy of the transfer gate line BLKSEL.

At time t1, the transistor T1 is turned on, and the selected transfer gate line BLKSEL goes to a high level. The voltage of the transfer gate line BLKSEL at this time is Vpgmh−2Vfb. Vpgmh is a voltage VRDEC supplied from the outside to the transistor T4 in the block decoder BD. Since the two diodes DD1 and DD2 are connected between the gate of the transistor T4 and the transfer gate line BLKSEL, the transfer gate line BLKSEL becomes a voltage level (Vpgmh−Vfb) obtained by subtracting a forward voltage Vfb of the diodes DD2 from the voltage Vpgmh. As described above, the intermediate node Va becomes a voltage higher than the transfer gate line BLKSEL by the forward voltage Vfb of the diode DD2.

When the second voltage Vz is raised at time t2, the voltage at the intermediate node Va is raised to a voltage Vpgmh+α by capacitive coupling of the capacitor Ca1. At this time, the voltage of the transfer gate line BLKSEL becomes a voltage (Vpgmh+α−Vfb) lower than the voltage Vpgmh+α of the intermediate node Va by the forward voltage Vfb.

Thereafter, when the second voltage Vz is lowered at time t3, the voltage at the intermediate node Va is also lowered by the capacitive coupling of the capacitor Ca1. The voltage of the intermediate node Va is lower than the voltage Vpgmh supplied from the outside to the transistor T4 by the forward voltage Vfb. At this time, the voltage Vy of the transfer gate line BLKSEL becomes a voltage lower than the voltage of the intermediate node Va by the forward voltage Vfb.

Thereafter, when the second voltage Vz is raised at time t4, the voltage of the transfer gate line BLKSEL is raised to (Vpgmh+α−Vfb) as the voltage of the intermediate node Va is raised, similarly to time t2.

For example, when the forward voltage Vfb of the diodes DD1 and DD2 is 0.8 V, the transfer gate line BLKSEL can be boosted to a voltage lower by 0.8 V than a voltage increase of the intermediate node Va due to the capacitive coupling of the capacitor Ca1.

As described above, the voltage level of the second voltage Vz applied to one end of the capacitor Ca1 is periodically raised or lowered, thereby making it possible to periodically boost the voltage level of the transfer gate line BLKSEL.

FIG. 9 is a diagram illustrating on-current characteristics of the transfer transistors TW0 to TW7, TS, and TD0 to TD4 according to the first embodiment. In FIG. 9, the horizontal axis represents a gate voltage [V] of each transfer transistor (the word line switch), and the vertical axis represents an on-current [A]. FIG. 9 illustrates three curves w1, w2, and w3 indicating on-current characteristics in a case where substrate bias voltages Vbs of the transfer transistors TW0 to TW7, TS, and TD0 to TD4 are changed in three ways (Vbs=around −10 V, around −15 V, around −20 V). Regardless of the substrate bias voltage Vbs, the on-current tends to increase as the gate voltage supplied by the transfer gate line BLK increases. For example, when the second voltage Vz is raised from Vpgmh to Vpgmh+α at the substrate bias voltage Vbs=around −20 V, the on-current moves from a plot p1 to a plot p2 in FIG. 9. In this manner, the on-current can be increased by increasing the second voltage Vz.

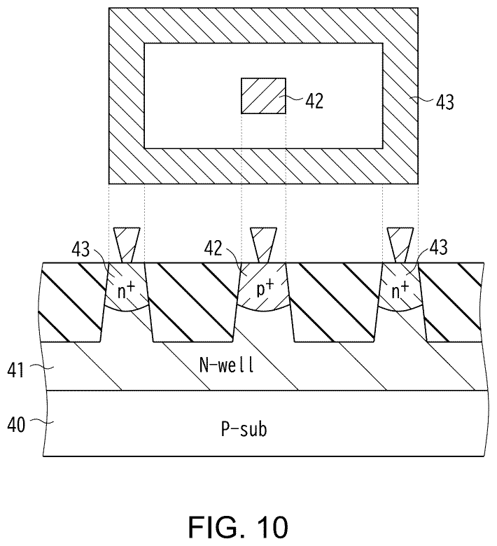

FIG. 10 is a plan view and a cross-sectional view illustrating structures of the diodes DD1 and DD2. Each of the diodes DD1 and DD2 is formed, for example, by joining a P-type diffusion region 42 and an N-type diffusion region 43 disposed in an N-well region 41 on a P-Si substrate 40. In the example of FIG. 10, the N-type diffusion region 43 is disposed so as to surround the periphery of the P-type diffusion region 42. An anode electrode is connected to the P-type diffusion region 42, and a cathode electrode is connected to the N-type diffusion region 43.

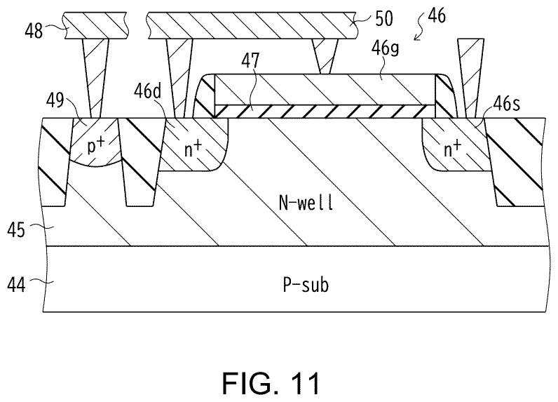

Each of the diodes DD1 and DD2 may have a structure in which a drain and a gate of an MOS transistor are short-circuited. FIG. 11 is a cross-sectional view in a case where the diodes DD1 and DD2 include the MOS transistors. In this case, a gate 46g and a drain 46d of an MOS transistor 46 arranged in an N-well region 45 on a P-type substrate 44 are short-circuited. FIG. 11 illustrates a cross-sectional structure of the diode DD2. A voltage Va is applied to the short-circuited gate 46g and drain 46d. Since a source 46s is connected to the transfer gate line BLKSEL, the source becomes the voltage Vy. The capacitor Ca1 having a gate insulating film 47 of the MOS transistor 46 as a dielectric layer is disposed. One electrode 48 of the capacitor Ca1 is connected to a P-type diffusion region 49 disposed in the vicinity of the MOS transistor 46. The voltage Vz is applied to the electrode 48. The other electrode 50 of the capacitor Ca1 is connected to the gate 46g and the drain 46d of the diode-connected MOS transistor 46.

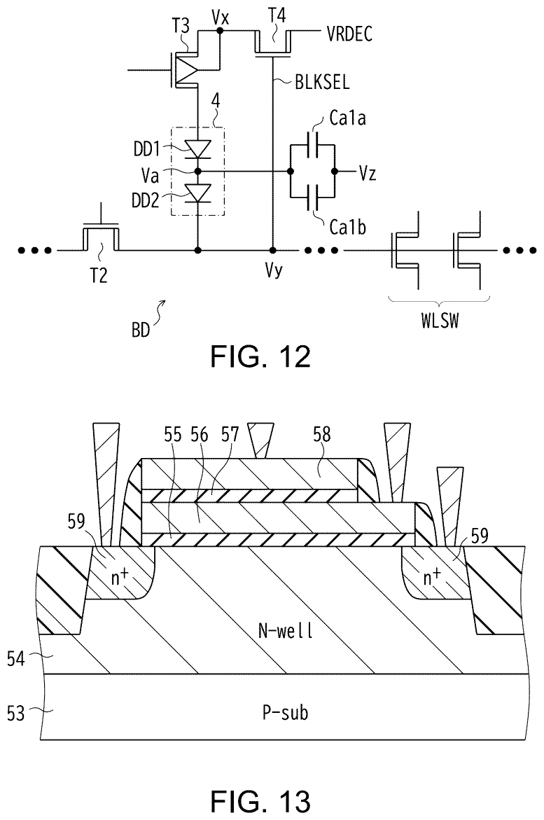

FIG. 12 is a circuit diagram of a block decoder BD according to a first modification of the first embodiment. A semiconductor device according to the first modification illustrated in FIG. 12 is characterized in that the capacitor Ca1 of the block decoder BD in FIG. 6 is replaced with two capacitors Ca1a and Ca1b connected in parallel. By connecting the two capacitors Ca1a and Ca1b in parallel between a node to which the second voltage Vz is applied and an intermediate node Va, the individual capacitors Ca1a and Ca1b are less likely to cause dielectric breakdown. In addition, areas of the individual capacitors Ca1a and Ca1b can be reduced as compared with FIG. 6.

FIG. 13 is a cross-sectional view of two capacitors Ca1a and Ca1b included in the block decoder BD according to the first modification. An inter-poly dielectric (IPD) film 57 is disposed on a gate insulating film 55 disposed on an N-well region 54 on a P-Si substrate 53 with a first conductive layer 56 interposed therebetween, and a second conductive layer 58 is disposed thereon. The first conductive layer 56 and the second conductive layer 58 may be polysilicon layers or metal layers. The first capacitor Ca1a is formed by sandwiching the IPD film 57 between the first conductive layer 56 and the second conductive layer 58. In addition, by sandwiching the gate insulating film 55 between the second conductive layer 58 and a source/drain diffusion layer 59, the second capacitor Ca1b connected in parallel to the first capacitor Ca1a is formed.

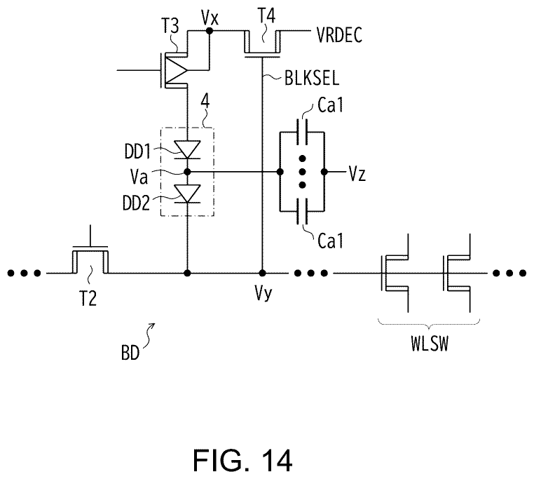

FIG. 14 is a circuit diagram of a block decoder BD according to a second modification of the first embodiment. In a semiconductor device according to the second modification illustrated in FIG. 14, three or more capacitors Ca1 are connected in parallel between a node to which the second voltage Vz is applied and the intermediate node Va. As a result, the individual capacitors Ca1 are less likely to cause dielectric breakdown than in FIG. 12.

In FIG. 14, three or more capacitors Ca1 are connected in parallel between a wiring to which the second voltage Vz is applied and a wiring of the intermediate node Va.

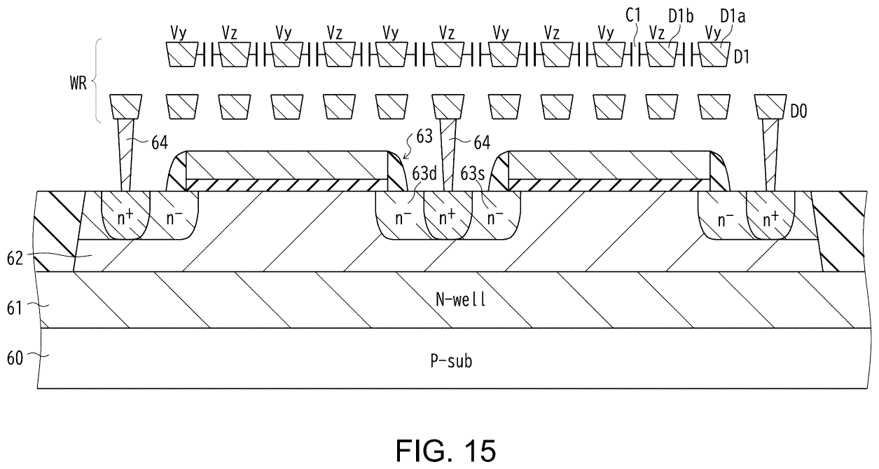

FIG. 15 is a cross-sectional view of the capacitor Ca1 according to the second modification. The capacitor Ca1 according to the second modification is disposed in the wiring layer region WR illustrated in FIG. 3. The wiring layers D0 and D1 are stacked in the wiring layer region WR, and for example, a wiring layer D1a to which the voltage Vy is applied and a wiring layer D1b to which the second voltage Vz is applied are alternately arranged in the wiring layer D1. The wiring layer Dla to which the voltage Vy is applied is a wiring layer connected to the transfer gate line BLKSEL. The capacitor Ca1 is disposed between the wiring layer D1a to which the voltage Vy adjacent in the substrate surface direction is applied and the wiring layer D1b to which the second voltage Vz is applied. As described above, by connecting the capacitor Ca1 between the two wiring layers D1a and D1b adjacent in the substrate surface direction, the number of capacitors Ca1 can be increased with a small area, and dielectric breakdown of each capacitor Ca1 can be prevented.

FIG. 15 illustrates an example in which a plurality of transfer transistors 63 are disposed in a P-type well region 62 disposed in a part of the N-type well region 61 disposed on a P-type silicon substrate 60. The two transfer transistors 63 adjacent to each other in the substrate surface direction share a drain region 63d or a source region 63s. Each of the drain region 63d and the source region 63s of each transfer transistor 63 is connected to separate electrodes provided in the wiring layer D0 via a contact 64.

As described above, in the block decoder BD according to the first embodiment, the second voltage Vz, the voltage level of which periodically changes, is applied to one end of the capacitor Ca1, and the other end of the capacitor Ca1 is connected to the intermediate node Va of the two diodes DD1 and DD2 connected in series between the drain of the transistor T3 and the transfer gate line BLKSEL. As a result, the voltage level of the transfer gate line BLKSEL can be periodically raised by capacitive coupling of the capacitor Ca1. Therefore, the voltage level of the transfer gate line BLKSEL can be boosted in accordance with a timing of writing data to a NAND string.

According to the present embodiment, since the periodic boosting operation of the transfer gate line BLKSEL can be performed only by the capacitor Ca1, the circuit configuration of the block decoder BD can be simplified. In addition, since the voltage is boosted by capacitive coupling, the voltage level of the transfer gate line BLKSEL can be quickly switched with low power consumption.

In addition, since the diodes DD1 and DD2 are connected between the drain of the transistor T3 and the transfer gate line BLKSEL, even when the transfer gate line BLKSEL is boosted, there is no possibility that a current flows from the transfer gate line BLKSEL to the drain of the transistor T3, thereby making it possible to stabilize an operation at the time of boosting the transfer gate line BLKSEL.

### Second Embodiment

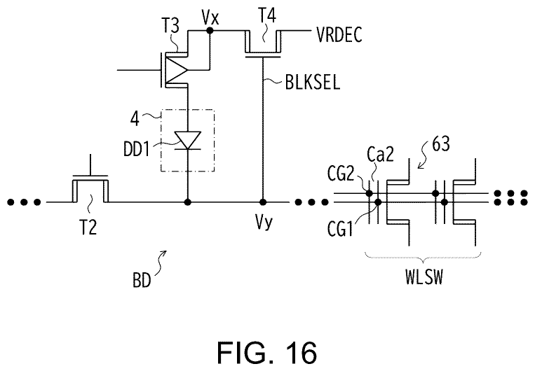

FIG. 16 is a circuit diagram of a block decoder BD according to a second embodiment. In FIG. 16, the same components as those in FIG. 6 are denoted by the same reference numerals, and differences therebetween will be mainly described below.

The block decoder BD according to the second embodiment illustrated in FIG. 16 includes a capacitor Ca2 connected to a place different from that in FIG. 6. Furthermore, the block decoder BD according to the second embodiment is also different from that of FIG. 6 in that one diode DD1 is connected between the drain of the transistor T3 and the transfer gate line BLKSEL.

The block decoder BD according to the second embodiment includes the capacitor Ca2 connected to the gate of a transfer transistor 63. The second voltage Vz is applied to one end CG2 of the capacitor Ca2, and the other end CG1 of the capacitor Ca2 is connected to the gate of the transfer transistor 63. As illustrated in FIG. 4, the transfer gate line BLKSEL is connected to each gate of the plurality of transfer transistors 63. The above-described capacitors Ca2 are separately connected to the respective gates of the plurality of transfer transistors 63. That is, each of the capacitors Ca2 is provided for a corresponding one of the plurality of transfer transistors 63. More specifically, the plurality of transfer transistors are transfer transistors TW0 to TW7, TS, TD0 to TD4, and the like.

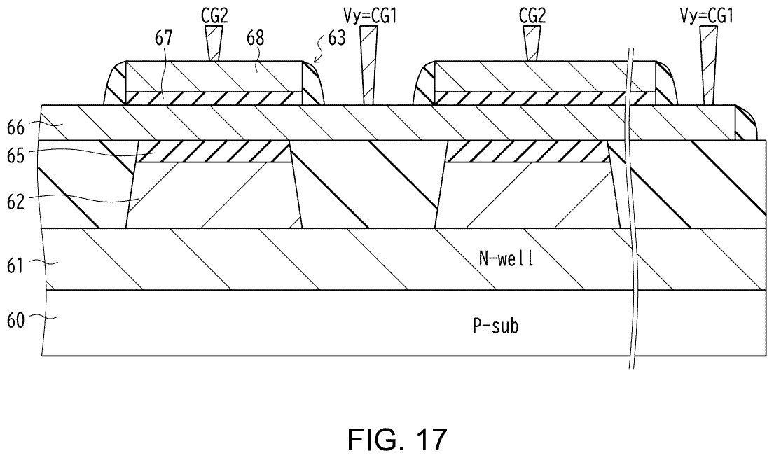

FIG. 17 is a cross-sectional view of the capacitor Ca2 included in the block decoder BD according to the second embodiment. FIG. 17 is a cross-sectional view of the transfer transistor 63 having a gate to which the other end of the capacitor Ca2 is connected. The transfer transistor 63 is provided in a plurality of P-type well regions 62 disposed in a part of an N-type well region 61 on a P-type silicon substrate 60. A gate insulating film 65 is disposed on the P-type well region 62, and a first polysilicon layer 66 is disposed thereon. An IPD film 67 is disposed on the first polysilicon layer 66, and a second polysilicon layer 68 is disposed thereon.

The capacitor Ca2 has a structure in which the IPD film 67 is sandwiched between the first polysilicon layer 66 and the second polysilicon layer 68. The transfer transistor 63 uses the first polysilicon layer 66 as a gate. A gate electrode CG1 is connected to the first polysilicon layer 66. An electrode CG2 is connected to the second polysilicon layer 68. The gate electrode CG1 is connected to the transfer gate line BLKSEL, and the voltage Vy is applied thereto. The second voltage Vz is applied to the electrode CG2.

When the voltage level of the second voltage Vz is raised, the gate voltage CG1 of the transfer transistor 63 is raised by capacitive coupling of the capacitor Ca2. Since the transfer gate line BLKSEL is connected to the gate of the transfer transistor 63, when the gate voltage of the transfer transistor 63 rises, the voltage Vy of the transfer gate line BLKSEL also rises. A diode is connected between the drain of the transistor T3 and the transfer gate line BLKSEL. Therefore, even if the voltage Vy of the transfer gate line BLKSEL increases, the current can be prevented from flowing from the transfer gate line BLKSEL to the drain of the transistor T3.

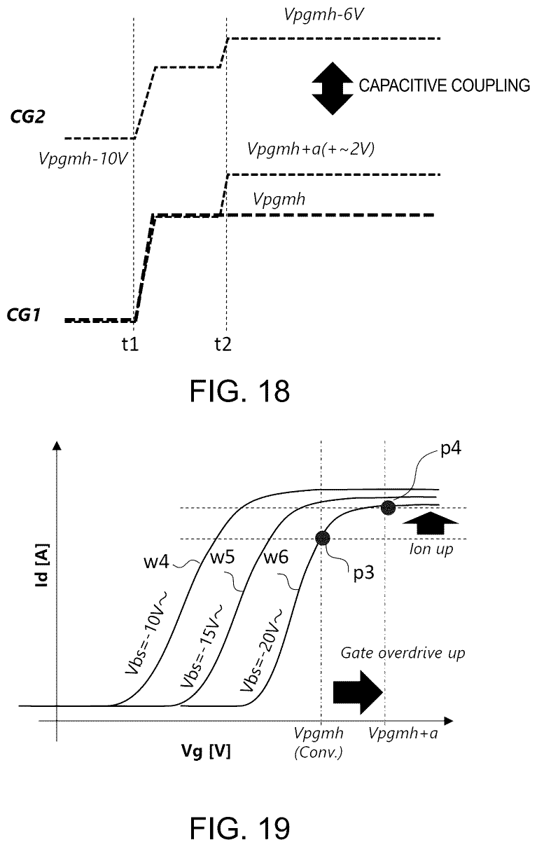

FIG. 18 is a diagram illustrating changes in voltage levels of the voltages CG1 and CG2 in FIG. 17. As described above, the voltage CG1 is the voltage Vy of the transfer gate line BLKSEL. The voltage CG2 is the second voltage Vz applied to one end of the capacitor Ca2.

When the voltage level of the voltage CG2 (the second voltage Vz) increases at time t1, the voltage level of the voltage CG1 (the transfer gate line BLKSEL) also increases due to capacitive coupling of the capacitor Ca2. Thereafter, when the voltage level of the voltage CG1 further increases at time t2, the voltage level of the voltage CG1 also further increases due to capacitive coupling of the capacitor Ca2.

FIG. 19 is a diagram illustrating on-current characteristics of the transfer transistor 63 according to the second embodiment. In FIG. 19, the horizontal axis represents a gate voltage [V] of each transfer transistor 63 (the word line switch), and the vertical axis represents an on-current [A]. FIG. 19 illustrates curves w4, w5, and w6 illustrating on-current characteristics in a case where the substrate bias voltages Vbs of the transfer transistors TW0 to TW7 and TS and TD0 to TD4 are changed in three ways. Regardless of the substrate bias voltage Vbs, the on-current tends to increase as the gate voltage increases. For example, when the second voltage Vz is raised from Vpgmh to Vpgmh+α at the substrate bias voltage Vbs=24 V, the on-current reliably increases as indicated by a plot p3 to a plot p4 in FIG. 19.

As described above, in the second embodiment, the capacitor Ca2 is connected to the gate of each transfer transistor 63, and the voltage CG1 (the second voltage Vz) applied to one end of the capacitor Ca2 is raised, thereby making it possible to quickly raise the gate voltage of each transfer transistor 63. As a result, the voltage level of the transfer gate line BLKSEL can be boosted without complicating the configuration of the block decoder BD.

### Third Embodiment

In the first and second embodiments described above, the boost voltage for the transfer gate line BLKSEL is generated using the capacitive coupling of the capacitors Ca1 and Ca2 inside the block decoder BD, whereas in the third embodiment, the boost voltage is generated on the front stage side of the row decoder RD having the block decoder BD incorporated therein.

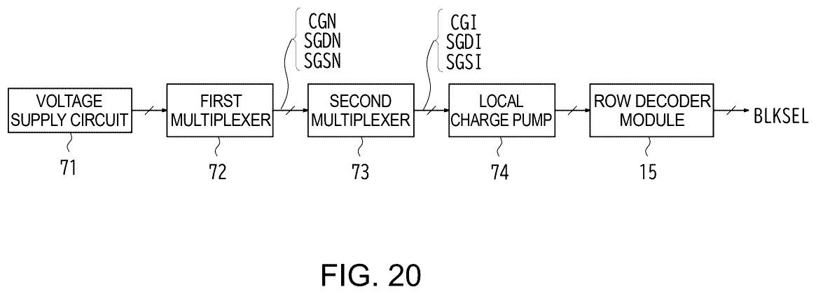

FIG. 20 is a block diagram illustrating a configuration on a transmission path of the voltage VRDEC supplied to each block decoder BD. A voltage supply circuit (a first boosting circuit) 71, a first multiplexer 72, a second multiplexer 73, a local charge pump (a second boosting circuit) 74, and a row decoder module 15 are connected to the above-described transmission path. The voltage supply circuit 71, the first multiplexer 72, the second multiplexer 73, the local charge pump 74, and the row decoder RD are built in, for example, the driver module 14.

The voltage supply circuit 71 generates a voltage of a predetermined voltage level. The first multiplexer 72 divides the voltage generated by the voltage supply circuit 71 into a plurality of systems. The second multiplexer 73 further divides each of the plurality of systems divided by the first multiplexer 72 into a plurality of systems. Each system divided by the second multiplexer 73 is, for example, for each block decoder BD.

The local charge pump 74 is provided for each row decoder module 15 in FIG. 4, for example, and boosts the voltage VRDEC to be applied to the corresponding block decoder BD as necessary.

The block decoder BD according to the third embodiment is configured similarly to FIG. 5. The local charge pump 74 generates a voltage VRDEC and supplies the voltage VRDEC to the corresponding block decoder BD. The local charge pump 74 increases the voltage level of the voltage VRDEC as necessary. Specifically, the voltage level of the voltage VRDEC is boosted at the time of data writing. The voltage VRDEC generated by the local charge pump 74 is applied to the drain of the transistor T4 in FIG. 5. The block decoder BD supplies a voltage corresponding to the voltage VRDEC to the transfer gate line BLKSEL. As described above, since each block decoder BD according to the third embodiment does not include a booster circuit like the block decoders BD according to the first and second embodiments, it is possible to further reduce a circuit size of the block decoder BD as compared with the first and second embodiments.

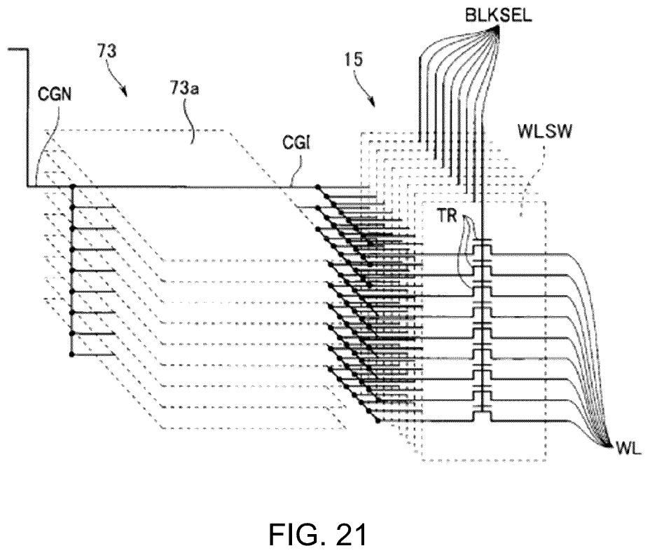

FIG. 21 is a diagram illustrating a path from an input of the second multiplexer 73 in FIG. 20 to a word line for one control signal line CGN. As described above, each row decoder RD in the row decoder module 15 includes a plurality of switch circuit groups (the word line switches) WLSW respectively corresponding to the plurality of block decoders BD.

As illustrated in FIG. 21, among the word lines of all the blocks, the word lines located in the same layer are connected to one control signal line CGI. The number of control signal lines CGI is the same as the number of word lines of one block BLK. The plurality of control signal lines CGI correspond to one control signal line CGN output from the first multiplexer 72. The second multiplexer 73 includes a plurality of second multiplexer units 73a, and each of the plurality of second multiplexer units 73a selects whether or not to supply the voltage transmitted through one control signal line CGN to the control signal line CGI corresponding to any one of the word lines.

FIG. 21 illustrates an example in which one control signal line CGN includes nine control signal lines CGI and nine blocks, and 9×9=81 word lines WL. Typically, several tens to several hundreds of control signal lines CGI, several thousands of blocks, and several tens of thousands or more of word lines are provided for several to several tens of control signal lines CGN. Therefore, a typical size relationship between the control signal line CGN, CGI, and the word line WL is CGN<CGI<WL. The same applies to the other control signal lines SGDN, SGDI, SGD, SGSN, SGSI, and SGS. For example, the number of other control signal lines is SGDN<SGDI<SGD, and SGSN<SGSI<SGS. Hereinafter, the control signal lines CGN, SGDN, and SGSN are collectively referred to as a control signal line GN.

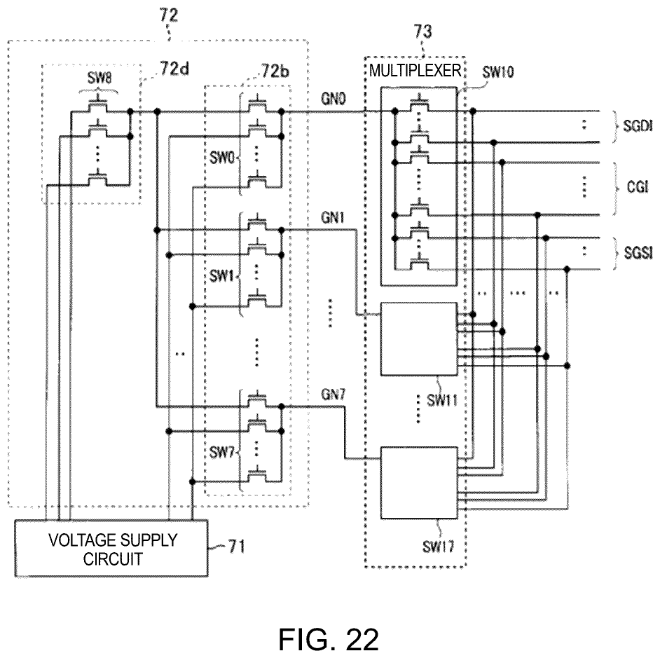

FIG. 22 is a diagram illustrating a wiring path from the voltage supply circuit 71 to the row decoder module 15. It is noted that the plurality of control signal lines GN are distinguished by adding a number after GN. FIG. 22 illustrates an example in which the eight control signal lines GN are provided, but the number of the control signal lines GN is freely selected.

The second multiplexer 73 includes switch groups SW10 to SW17 including a plurality of switches. The switch groups SW10 to SW17 have the same configuration. A control signal line GN0 is commonly connected to an input end of each switch of the switch group SW10. An output terminal of each switch of the switch group SW10 is connected to a corresponding one of the control signal lines SGDI, CGI, and SGSI. The switch group SW10 determines whether or not to supply a voltage supplied via the control signal line GN0 to any of the control signal lines. For example, when a read voltage VCGRV is transmitted by the control signal line GN0, each switch of the switch group SW10 is controlled so as to supply the read voltage VCGRV to the control signal line CGI corresponding to the word line WL to be read.

Similarly, input ends of the respective switches of the switch groups SW10 to SW17 are connected to the control signal lines GN0 to GN7, respectively, as illustrated in FIG. 22. Further, the output ends of the switch groups SW10 to SW17 are connected to the control signal lines SGDI, CGI, and SGSI as illustrated in FIG. 22.

The switches of the switch groups SW10 to SW17 are controlled so as to supply the voltages respectively transmitted by the control signal lines GN0 to GN7 to the control signal lines SGDI, CGI, and SGSI corresponding to the control signal lines SGD, WL, and SGS in the memory cell array 10 to be supplied. In this way, voltages corresponding to the control signal lines SGDI, SGSI, and CGI are supplied from the second multiplexer 73. For example, during the write operation, each switch of the switch group to which a voltage VPASS is transmitted by the control signal line GN is controlled so as to supply the voltage VPASS to the plurality of control signal lines CGI corresponding to the unselected word line.

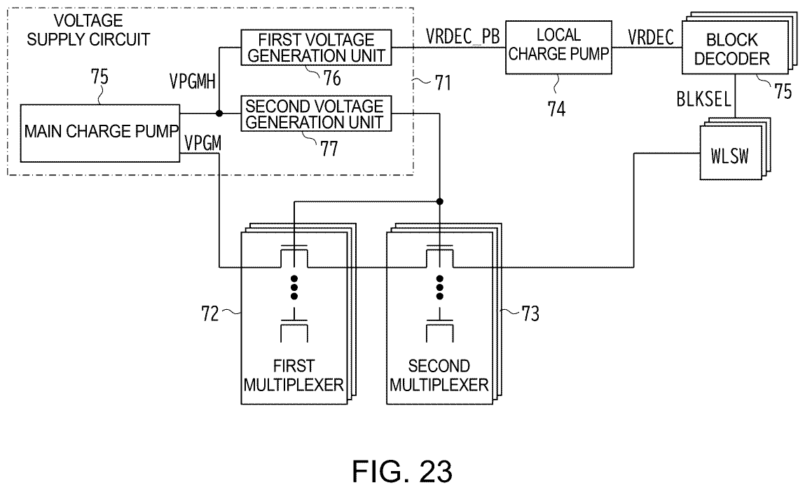

FIG. 23 is a block diagram illustrating a connection relationship between the voltage supply circuit 71 and the local charge pump 74. The voltage supply circuit 71 includes a main charge pump 75, a first voltage generation unit 76, and a second voltage generation unit 77.

The main charge pump 75 generates a voltage VPGMH supplied to the plurality of first voltage generation units 76 and the plurality of second voltage generation units 77 and a voltage VPGM supplied to the first multiplexer 72.

The first voltage generation unit 76 and the second voltage generation unit 77 are provided for each row decoder module 15, that is, in association with the plurality of block decoders BD in the row decoder module 15. That is, each of the plurality of first voltage generation units 76 generates a voltage VRDEC_PB for the corresponding block decoder BD. Similarly, each of the plurality of second voltage generation units 77 generates a voltage VRDEC_HVSW for the corresponding block decoder BD. A voltage VRDEC_VSW generated by each of the plurality of second voltage generation units 77 is input to the gate of each transistor included in the first multiplexer 72 and the second multiplexer 73.

The local charge pump 74 uses the voltage VRDEC_PB generated by the first voltage generation unit 76 to generate the voltage VRDEC for boosting the transfer gate line of the corresponding block decoder BD.

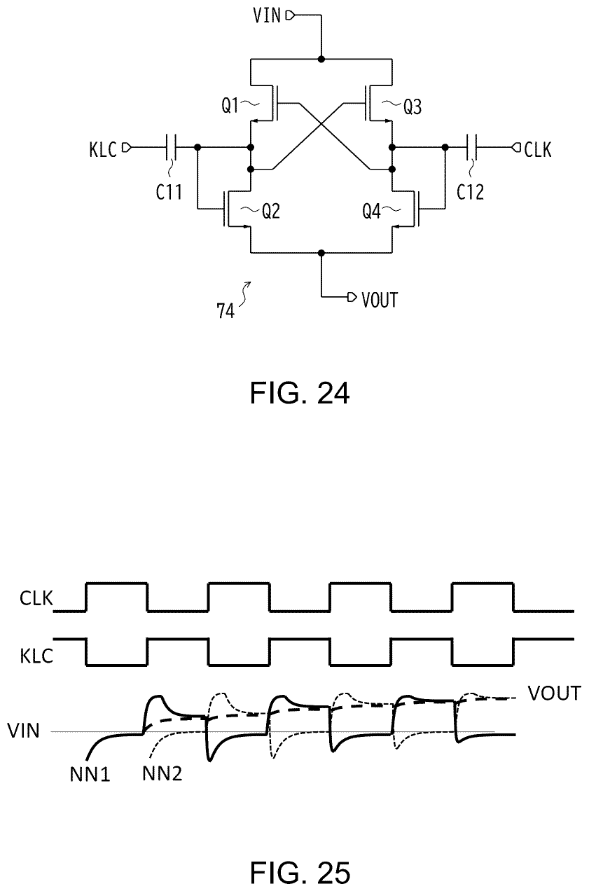

FIG. 24 is a circuit diagram illustrating an example of an internal configuration of the local charge pump 74. As illustrated in FIG. 24, the local charge pump 74 includes first to fourth transistors Q1 to Q4 and first and second capacitors Ca11 and Ca12. Each of the first to fourth transistors Q1 to Q4 is an NMOS transistor. The drain of the first transistor Q1 and the drain of the third transistor Q3 are connected to an input voltage node VIN. The source of the first transistor Q1 is connected to the drain of the second transistor Q2, and the source of the second transistor Q2 is connected to an output voltage node VOUT. The source of the third transistor Q3 is connected to the drain of the fourth transistor Q4, and the source of the fourth transistor Q4 is connected to the output voltage node VOUT. The source of the third transistor Q3 and the drain of the fourth transistor Q4 are connected to the gate of the first transistor Q1. The source of the first transistor Q1 and the drain of the second transistor Q2 are connected to the gate of the fourth transistor Q4. An inverted clock signal KLC is input to the first electrode of the first capacitor Ca11, and the gate of the third transistor Q3, the source of the first transistor Q1, and the drain of the second transistor Q2 are connected to the second electrode of the first capacitor Ca11. A clock signal CLK is input to the first electrode of the second capacitor Ca12, and the gate of the first transistor Q1, the source of the third transistor Q3, and the drain of the fourth transistor Q4 are connected to the second electrode of the second capacitor Ca12. The voltage VRDEC_PB generated by the first voltage generation unit 76 is applied to the input voltage node VIN.

It is noted that FIG. 24 is merely an example of an internal configuration of the local charge pump 74. The local charge pump 74 may have an internal configuration different from that of FIG. 24.

FIG. 25 is a voltage waveform diagram of a signal input to and output from the local charge pump 74. FIG. 25 illustrates voltage waveforms of the clock signal CLK, the inverted clock signal KLC, the voltage VRDEC_PB input to the input voltage node, the voltage NN1 of the second electrode of the first capacitor Ca11, a voltage NN2 of the second electrode of the second capacitor Ca12, and the voltage VOUT output from the output voltage node. As illustrated in FIG. 25, the voltage VOUT gradually increases as the number of clocks of the clock signal CLK increases.

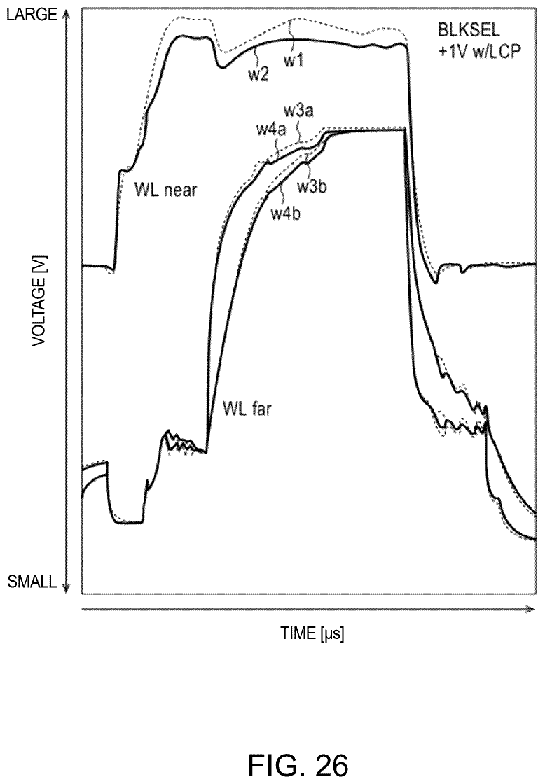

FIG. 26 is a voltage waveform diagram of the block decoder BD according to the third embodiment. FIG. 26 illustrates voltage waveforms w1 in a case where the voltage of the transfer gate line BLKSEL in the block decoder BD in FIG. 23 is boosted by the local charge pump 74, a voltage waveform w2 in a case where the voltage is not boosted, and voltage waveforms w3a and w3b after the boosting and voltage waveforms w4a and w4b before the boosting of the word line connected to the word line switch WLSW. The voltage waveforms w3a and w4a indicate voltage waveforms of word lines located near the block decoder BD, and the voltage waveforms w3b and w4b indicate voltage waveforms of word lines located far away from the block decoder BD.

As illustrated in FIG. 26, when the voltage VRDEC is boosted by the local charge pump 74 in FIG. 23, the voltage of the transfer gate line BLKSEL in a lock decoder is boosted by about 1 volt, and the voltage level of the word line is also boosted.

As described above, in the third embodiment, since the local charge pump 74 for boosting the voltage supplied to each block decoder BD in the row decoder module 15 is provided on the front stage side of the row decoder module 15, the overall circuit size of the semiconductor memory device can be reduced without providing each block decoder BD with an additional boosting function.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

1. A semiconductor device comprising:
a control wiring connected to a gate of a first transistor;
a second transistor including a first terminal and a second terminal each serving as a source or a drain, and a first gate having the control wiring connected thereto, wherein the first terminal has a first voltage input thereto, wherein the first voltage is provided to turn on the first transistor;
a third transistor including a third terminal and a fourth terminal each serving as a source or a drain, and a second gate, wherein the third terminal is connected to the second terminal, the fourth terminal controls a voltage of the control wiring, and the third transistor is turned on by a first control signal input to the second gate when the first transistor is turned on;
a fourth transistor including a fifth terminal and a sixth terminal each serving as a source or a drain, and a third gate, wherein the fourth transistor is turned on by a second control signal input to the third gate when the third transistor is turned on and is turned off by a second control signal input to the third gate when the third transistor is turned off; and
a capacitor configured to boost, by capacitive coupling, a second voltage output from the fourth terminal in a state in which the first transistor and the second transistor are turned on to a third voltage higher than the second voltage, and to supply the third voltage to the control wiring.

2. The semiconductor device according to claim 1, further comprising
a rectifier circuit configured to prevent a current due to the boosted voltage of the control wiring from flowing between the drain and the source of the third transistor.

3. The semiconductor device according to claim 2,
wherein each of the second transistor and the fourth transistor is an N-type metal oxide semiconductor (MOS) transistor,
the third transistor is a P-type MOS transistor, and
the rectifier circuit is disposed between a drain of the P-type MOS transistor and the control wiring.

4. The semiconductor device according to claim 2,
wherein the rectifier circuit is a diode including an anode connected to the drain of the third transistor and a cathode connected to the control wiring, or is a diode-connected MOS transistor.

5. The semiconductor device according to claim 4,
wherein the rectifier circuit includes a first diode and a second diode connected in series between the drain of the third transistor and the control wiring, and
the capacitor boosts, by the capacitive coupling, a voltage level of an intermediate node to which a cathode of the first diode and an anode of the second diode are connected.

6. The semiconductor device according to claim 5,
wherein the capacitor has one end connected to the intermediate node, and
the capacitor has the other end to which the second voltage is applied, the voltage level of the second voltage being variable.

7. The semiconductor device according to claim 1,
wherein the control wiring has a voltage level corresponding to a voltage of one end of the capacitor, and
the capacitor has the one end to which the second voltage is applied, a voltage level of the second voltage being variable.

8. The semiconductor device according to claim 7,
wherein the second voltage is a clock signal having a periodically changing voltage level, and
the control wiring is repeatedly boosted in synchronization with a cycle of the clock signal.

9. The semiconductor device according to claim 7,
wherein a plurality of the capacitors connected in parallel are provided between the control wiring and an application node of the second voltage.

10. The semiconductor device according to claim 1,
wherein the capacitor is an MOS capacitor including a gate insulating film having a film thickness equal to or less than a film thickness of a gate insulating film of each of the second to fourth transistors.

11. The semiconductor device according to claim 1, further comprising
a plurality of the first transistors having the respective gates connected to the control wiring,
wherein each of the plurality of first transistors causes a larger on-current to flow between the drain and the source when the control wiring is boosted compared to when the control wiring is not boosted.

12. The semiconductor device according to claim 1, further comprising
a dielectric layer and a conductive layer stacked on the gate of the first transistor,
wherein the capacitor includes the gate of the first transistor, the dielectric layer, and the conductive layer,
the second voltage is applied to the conductive layer, a voltage level of the second voltage being variable, and
the first transistor has a gate voltage variably controlled by the capacitive coupling of the capacitor.

13. The semiconductor device according to claim 1, further comprising
a decoder configured to select a control wiring to be boosted from among the plurality of control wirings,
wherein the decoder includes, for each of the plurality of control wirings, the second transistor, the third transistor, the fourth transistor, and the capacitor.

14. The semiconductor device according to claim 13, further comprising:
a plurality of memory strings each including a plurality of memory cell transistors and control transistors connected in series;
a plurality of first wirings connected to each gate of the plurality of memory cell transistors and control transistors, respectively; and
a plurality of transfer transistors configured to switch whether or not to drive the plurality of first wirings,
wherein the decoder switches whether or not to drive, as the control wiring, each gate line of the plurality of transfer transistors in the selected memory string.

15. A semiconductor device comprising:
a voltage supply circuit configured to generate a first voltage commonly used to boost a plurality of control wirings;
a booster circuit provided corresponding to the plurality of control wirings and configured to generate, based on the first voltage, a second voltage higher than the first voltage; and
a plurality of decoders configured to control, based on the second voltage, whether or not to boost the corresponding control wiring.

16. The semiconductor device according to claim 15, further comprising:
a plurality of memory strings each including a plurality of memory cell transistors and control transistors connected in series; and
a memory cell array configured to erase data for each of a plurality of blocks each having the plurality of memory strings,
wherein the plurality of decoders is provided in association with the plurality of blocks.

17. The semiconductor device according to claim 16,
wherein each of the plurality of decoders includes:
first transistor configured to switch, according to the corresponding second voltage, whether or not to boost a voltage of a gate connected to the corresponding control wiring;
a second transistor turned on when the corresponding control wiring is boosted; and
a third transistor turned off when the corresponding control wiring is boosted.

18. The semiconductor device according to claim 1,
wherein each of the first transistor, the second transistor, and the third transistor is a high breakdown voltage transistor.
